(19) United States
(12) Patent Application Publication
(10) Pub. No.: US 2005/0239219 A1
(43) Pub. Date: Oct. 27, 2005

(54) Process for fabrication of a ferrocapacitor with a large effective area

(76) Inventor: Bum-Ki Moon, Poughkeepsie, NY (US)

Correspondence Address: SLATER & MATSIL LLP, 17950 PRESTON ROAD, SUITE 1000, DALLAS, TX, 75252, US

(21) Appl. No.: 10/831,957

(22) Filed: Apr. 26, 2004

(51) Int. Cl. H01L 21/00; H01L 21/8242; H01L 29/76

(52) U.S. Cl. 438/3; 438/240; 438/785; 257/295

(57) ABSTRACT

In a ferroelectic capacitor including a dielectric ferroelectric element sandwiched between a bottom electrode and top electrode, the bottom electrode is formed with a ridged structure, and the ferroelectric layer is formed over it and on its sides. Thus the dielectric between the top and bottom electrodes includes not just horizontal sections but also non-horizontal sections. The inventive structure thus has a higher effective capacitor area compared to the overall area of the device. This has two advantages. Firstly, it means that the total charge which can be stored in the device is higher. Secondly, it means that damage to the electrodes and the ferroelectric element at their edges regions occupies a lower proportion of the effective area of the device. The ridged structure of the bottom electrode may be due to it being formed over a ridged substructure, or because it is itself selectively etched.

### FIELD OF THE INVENTION

The present invention relates to fabrication processes for ferroelectric devices which include one or more ferrocapacitors, and to ferroelectric devices produced by the fabrication processes.

### BACKGROUND OF INVENTION

It is known to produce ferroelectric devices such as FeRAM devices including ferroelectric capacitors produced by depositing the following layers onto a substructure (frequently including a barrier film) of interlayer dielectric (ILD) material: a bottom electrode layer, a ferroelectric layer, and a top electrode layer. Hardmask elements, typically formed Tetraethyl Orthosilicate (TEOS), are deposited over the top electrode layer, and used to etch the structure so as to remove portions of the bottom electrode layer, ferroelectric layer, and top electrode layer which are not under the hardmask elements. The etching separates the top electrode layer into top electrodes, the bottom electrode layer into bottom electrodes, and the ferroelectric layer into ferroelectric elements sandwiched by respective pairs of top electrodes and bottom electrodes. The structure is illustrated in FIG. 1. It includes substructure 1, bottom electrode 3, ferroelectric layer 5 and top electrode 7, and is covered by an encapsulation layer 9. Note that in known variations of this structure the bottom electrode may extend between two (or more) of the capacitors (i.e. be shared between them). Typically the substructure 1 includes conductive plugs extending upwardly through it, but these are not shown in FIG. 1. This is because the ferrocapacitor is a so-called “offset cell structure”.

The total charge which can be stored in the device (conventionally written as Q_{sw}) depends on the area of the top surface of the electrode 3. Conventional techniques for improving this charge capacity are directed to improvement of the ferroelectric quality of the ferroelectric element 5 or by employing a material having a high remnant polarization, but these techniques have limited effectiveness. Furthermore, the edge regions 2 of the layers 3, 5, 7 of the ferrocapacitor suffer some damage during the etching process which is carried out to singulate the ferrocapacitors, and this reduces the effective area of the ferrocapacitor further.

### SUMMARY OF THE INVENTION

The present invention aims to provide a new and useful process for fabricating ferrocapactitors, and to provide devices including such ferrocapacitors.

In general terms, the present invention proposes that the bottom electrode should be formed with a ridged structure, and the ferroelectric layer is formed over it and on its sides. As in conventional devices, a top electrode layer is formed covering the ferroelectric layer, and then at least the top electrode layer and ferroelectric layer are etched to form individual capacitors. Thus, within a given capacitor, the dielectric layer between the top and bottom electrodes includes not just horizontal sections but also non-horizontal sections.

The inventive structure thus has a higher effective capacitor area, for a given overall area of the device. This has two advantages. Firstly, it means that the total charge which can be stored in the device is higher. Secondly, it means that the damaged portions of the layers (particularly their edge regions where they are etched) constitute a lower proportion of the total effective area of the device, which means for example that the performance of the device is more predictable.

In a first case, the ridges of the bottom electrode can be formed by a selective etching of the bottom electrode itself. For example, the bottom electrode may be formed as an initially uniform flat layer and be selectively etched to leave a structure including ridges.

Alternatively, the ridges of the bottom electrode can be formed by depositing the bottom electrode over an uneven in the substructure. For example, the substructure may include ridges over which the bottom electrode is deposited, so that the bottom electrode at least partially adopts that ridged structure.

In either case, the ridges formed in the bottom electrode may have substantially any pattern within the scope of the invention.

For example, considering the cross-section of the ridges, each ridge may have a rectangular cross-sectional profile, or alternatively a rounded one.

Furthermore, imagining viewing at the bottom electrode from above, the ridges may spread over laterally in any pattern. For example, each ridge may be a single straight line (i.e. it may have a straight longitudinal axis of symmetry). Each ridge may in fact only be as long as its width, so as to be a substantially square upstanding area of the bottom electrode.

More preferably, however, the ridges are not straight along the whole of their length. For example, preferably, the ridges for a given capacitor at least partially encircle an area of the capacitor, such that both the inwardly and outwardly directed surfaces of the ridge constitute parts of the capacitor. In a particularly preferred form of the invention, the ridges have an arrow shape, e.g. including two portions having longitudinal axes which meet each other at an angle of greater than 90 degrees.

Specifically, a first expression of the invention is a method of forming a ferroelectric capacitor including the steps of:
depositing a bottom electrode layer having a ridged structure;
depositing a ferroelectric layer over the ridged structure;
depositing atop electrode layer over the ferroelectric layer; and
etching at least the top electrode layer to form a top electrode element, and the ferroelectric layer to form a ferroelectric element.

### BRIEF DESCRIPTION OF THE FIGURES

Preferred features of the invention will now be described, for the sake of illustration only, with reference to the following figures in which:

FIG. 1 is a cross-sectional view of a known ferroelectric capacitor;

FIG. 2 is a cross-sectional view of a first embodiment of the invention;

FIG. 3 is a cross-sectional view of a second embodiment of the invention;

FIG. 4 is a cross-sectional view of a third embodiment of the invention;

FIG. 5 is a cross-sectional view of a fourth embodiment of the invention; and

FIG. 6 is a perspective view of the ridges in the bottom electrode in a second embodiment of the invention.

### DETAILED DESCRIPTION OF THE EMBODIMENTS

Referring to FIG. 2, a ferrocapacitor which is a first embodiment of the invention is shown. This capacitor may be of the “offset cell” type. The formation process is as follows. A substructure 11 is initially planar, but it is selectively etched (e.g. using a mask, which is subsequently removed). The areas of the substructure 11 which are not etched in this process remain as ridges 10.

As in the conventional fabrication technique, a bottom electrode layer 13 (e.g. of Pt) is then deposited over the substrate 13. The portions of the bottom electrode layer 13 which overlie the ridges 10 form a ridged structure. The bottom electrode layer 13 thus comprises lower horizontal portions 16, upper horizontal portions 14 and upright portions 12.

Over the bottom electrode layer 13, a ferroelectric layer 15 is formed (e.g. a material such as PZT). Some portions of the layer 15 are over the flat surface of the upper portions 14 of the layer 13, while other portions of the layer 15 are over the lower portions 16 of the layer 13, while other portions of the layer 15 are on the side surfaces of the upright portions 12. Over the ferroelectric layer 15 is formed a top electrode layer 17 (e.g. again of Pt), which adopts a configuration corresponding to that of the ferroelectric layer 15.

The top electrode layer 17 is then covered with a hard mark element (not shown) which covers all of the region marked 111, and an etching operation is performed so that the portions of the bottom electrode layer 13, ferroelectric layer 15, and top electrode layer 17 outside the region 111 are removed, as shown in FIG. 2. As in conventional methods, this leaves a certain amount of damage in the areas marked 112 at the edges of the remaining portions of the layers 13, 15, 17. Then an encapsulation layer 19 is deposited over the entire structure, as in conventional methods. Finally, an ILD layer 18 is deposited over the entire structure.

The side portions 12 of the bottom electrode 13, and the portions of the ferroelectric layer 15 and top electrode layer 17 which are on the sides of the portions 12 contribute to the effective capacitive area of the ferrocapacitor. Thus, the effective area of the ferrocapacitor includes the areas over the horizontal portions 14, 16 of the bottom electrode 13 (which are together roughly equivalent to the effective area of a conventional capacitor) plus the areas on the sides 12 of the ridges 10. This means that the total charge which can be stored in the capacitor is higher than in conventional devices having the same actual area (i.e. the area 111). Furthermore, this also means that the proportion of the effective area of the capacitor which is ineffective due to the damage in the regions 112 is lower than in conventional devices. The shape and effective area of the ferroelectric layer can be controlled by the etching conditions used to etch the layer 11.

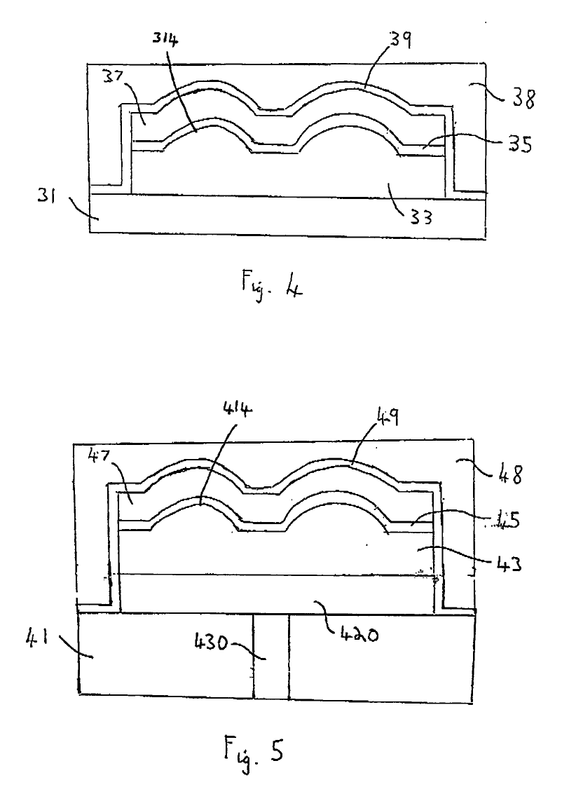

Turning to FIG. 3, a second embodiment of the invention is shown. Whereas in the first embodiment of the invention, the ridged structure is formed by etching a sacrificial portion of the substructure 1, the second embodiment of the invention is produced by a process which does not include a step in which the substructure 21 is selectively etched. Instead, the bottom electrode layer 23 is initially formed to be thick enough (e.g. thicker than in the first embodiment of FIG. 2), that it can be selectively etched itself to form a ridged structure, in which the bottom electrode includes.

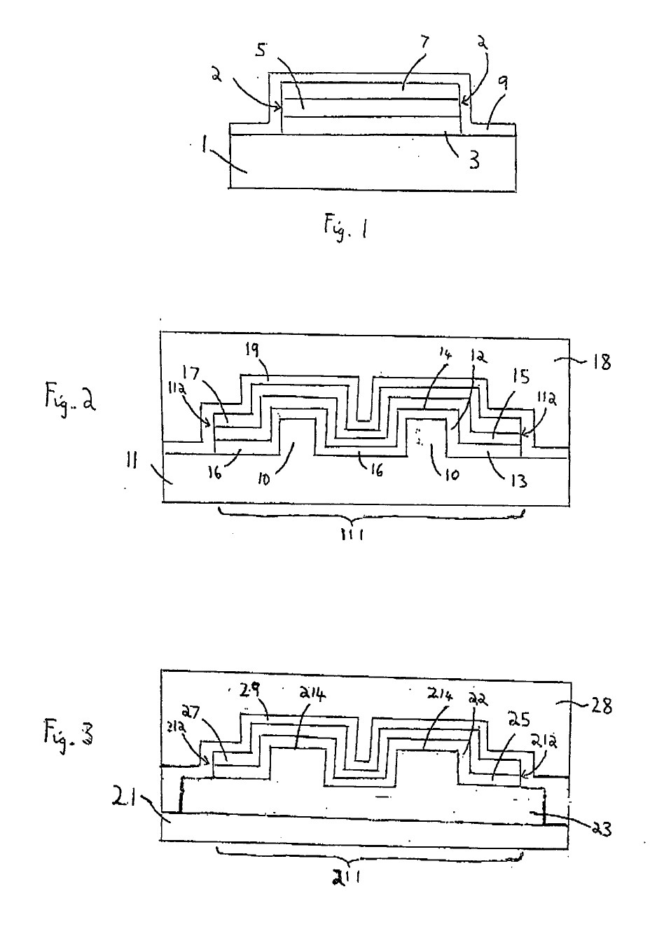

Specifically, the first steps of the formation method of the second embodiment of the invention are that over a substructure 21 (which is as in the known structure of FIG. 1) is formed a bottom electrode layer 23 which is thicker than that used to produce the structure of FIG. 1. The bottom electrode layer 23 is selectively etched (e.g. by RIE—reactive ion etching), leaving ridges 214. This etching may also include etching of the sides of the bottom electrode layer 23.

Then the steps used to produce the first embodiment of the invention are carried out. That is, a ferroelectric layer 25 is deposited over the bottom electrode layer 23, including portions 22 of dielectric material on the sides of the ridges 214. Then, a top electrode layer 27 is deposited over the ferroelectric layer 25. Then a mask (not shown) is deposited over the whole of the area marked as 211, and used to etch the layers 23, 25, leaving damaged areas 212. Note, however, that the bottom electrode 23 is wider than the ferroelectric element 25 and top electrode 27, which means that there is little chance of the ferroelectrode being damaged due to the etching of the bottom electrode. Then an encapsulation layer 29 is deposited over the structure, and an ILD layer 28 over that. The shape and effective area of the ferroelectric layer can be controlled by the etching conditions used to etch the bottom electrode layer 23.

In either of FIG. 2 or FIG. 3 the amount by which the layers 11 or 23 respectively are etched may for example be in the range 20 to 180 nm, e.g. about 100 nm.

FIG. 4 shows a third embodiment of the invention which would be produced if the etching conditions used to form the ridges 214 of FIG. 3 are different, so that the ridges 214 are replaced by rounded ridges 314. Other elements of the embodiment of FIG. 4 corresponding to those of FIG. 3 are shown by reference numerals in which the first digit “2” is replaced by “3”.

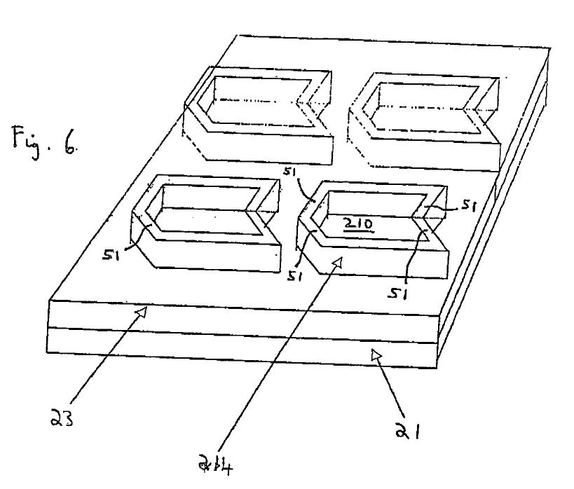

Similarly, FIG. 5 shows a fourth embodiment of the invention which would be produced if the bottom electrode 33 of FIG. 4 were instead a bottom electrode 43 located over a barrier layer 420, which is in turn formed over a conductive plug 430 which extends downwardly through an IMD layer 41 to other components (not shown) of the device. That is, FIG. 5 shows a COP (capacitor-on-plug) structure, rather than the offset cell structure of FIGS. 1 to 4. Other elements of the embodiment of FIG. 5 corresponding to those of FIG. 4 are shown by reference numerals in which the first digit “3” is replaced by “4”. The fabrication technique of the capacitor structure of FIG. 5 corresponds to that of FIG. 4, except that the barrier layer 420 is formed by deposition before the bottom electrode layer 43, and the two are etched at the same time as the layers 43, 45, 47.

The cross-sectional views of FIGS. 2 to 5 indicated the cross-sectional shapes of the ridges, but only partly indicate the arrangement of the ridges 10, 214, 314, 414 over the substructures 11, 21, 31, 41. This arrangement is shown in the perspective view of FIG. 6, which illustrates the embodiment of FIG. 3 before the deposition of the ferro-electric layer 25. The ridges 214 have an arrow shaped arrangement, in which the ridges surround and define respective recesses 210. At each end of the arrow, the ridges form lines 51 which meet each other at an obtuse angle. The ridges 10, 314, 414 may have this arrangement too, or a different arrangement.

Although only four embodiments of the invention have been described in detail, many variations are possible within the scope of the invention, as will be clear to a skilled reader. For example, although in FIG. 6 the ridges 214 have an arrow-shaped arrangement, in which there is a single acute angle, the invention is not limited in this respect and many other arrangements are possible, such as a star-shaped ridge having more than one acute angle.

1. A ferroelectric capacitor comprising:
a substructure;
a bottom electrode formed over the substructure and having a ridged structure;
a ferroelectric element over the ridged structure; and
a top electrode over the ferroelectric element.

2. A ferroelectric capacitor as claimed in claim 1 having an offset cell structure.

3. A ferroelectric capacitor as claimed in claim 1 having a capacitor-on-plug structure in which the bottom electrode is formed partly over a conductive plug.

4. A ferroelectric capacitor as claimed in claim 1 in which the substructure has a ridged structure, the ridges in the bottom electrode overlying the ridges in the substructure.

5. A ferroelectric capacitor as claimed in claim 1 in which the bottom electrode is of varying thickness thereby defining the ridged structure.

6. A ferroelectric capacitor as claimed in claim 1 in which the ridged structure includes elongate ridges in a pattern over the substructure.

7. A ferroelectric capacitor as claimed in claim 6 in which the elongate ridges encircle recesses.

8. A ferroelectric capacitor as claimed in claim 6 in which the elongate ridges include regions in which two elongate ridge portions meet at an obtuse angle.

9. An FeRAM memory device including a plurality of ferroelectric capacitors as claimed in claim 1.

10. A method of forming a ferroelectric capacitor including the steps of:
depositing a bottom electrode layer having a ridged structure;
depositing a ferroelectric layer over the ridged structure;
depositing a top electrode layer over the ferroelectric layer; and
etching at least the top electrode layer to form a top electrode element, and the ferroelectric layer to form a ferroelectric element.

11. A method according to claim 10 in which the bottom electrode layer is formed over a substructure, the method including a step, prior to the step of depositing the bottom electrode layer, of etching the substructure to give it a ridged structure, the ridged structure of the bottom electrode layer being due to the ridged structure of the substructure.

12. A method according to claim 8 which includes a step, prior to the step of depositing the ferroelectric layer, of etching the bottom electrode layer to give it the ridged structure.
